(19) United States
(12) Patent Application Publication
(10) Pub. No.: US 2016/0247532 A1
(43) Pub. Date: Aug. 25, 2016

(54) STORAGE MEDIUM VACUUM SPUTTER TOOL ADJUSTABLE IDLER

(71) Applicant: Seagate Technology LLC, Cupertino, CA (US)

(72) Inventors: Samuel L. Tanaka, Fremont, CA (US); ChunWai Joseph Tong, San Jose, CA (US); Thomas L. Greenberg, Berkeley, CA (US)

(21) Appl. No.: 14/629,054

(22) Filed: Feb. 23, 2015

(51) Int. Cl. G11B 5/851; H01J 37/34; C23C 14/34

(52) U.S. Cl. CPC G11B 5/851; C23C 14/34; H01J 37/3405; H01J 2237/3323

(57) ABSTRACT

A coating apparatus for magnetic data storage disks is operable to transport a disk in a disk holding fixture from a first coating area to a second coating area via roller wheels along a first path. A wheel located along the first path between the first coating area and the second coating area within a sealed enclosure is adjusted such that deflection of the disk holding fixture when traversing the disk transport wheel is reduced, such as by adjusting a leadscrew coupled to the disk holding fixture and a frame of the disk coating apparatus. Adjustment is made with the disk coating apparatus sealed and under vacuum, as the position of the disk transport wheel being adjusted may be different under vacuum than under atmospheric pressure. Adjustment is verified by processing a test disk and measuring forces applied to the test disk during transport through the disk coating apparatus.

### FIELD

The disclosure relates generally to storage media processing, and more specifically to adjustable idler use in a storage medium vacuum sputter tool.

### BACKGROUND

Data storage systems such as hard disk drives commonly have one or more data storage media, such as a magnetic disk, and one or more elements that communicate with the data storage medium to read and write data. Hard disk drives, for example, typically employ one or more rotating disks or platters that are coated with a magnetic material, such that it retains data magnetically stored on the disk even when the disk drive is powered off. One or more magnetic heads are configured to read the magnetic data stored on the surfaces of the one or more disks, and to write magnetic data to the disks. The heads can be located to various positions on the magnetic disks as the disks spin, enabling the hard disk drive to provide random access, or to read and write individual blocks of data in any order.

The disks in a disk drive typically spin at speeds from 5,400 revolutions per minute to 10,000 revolutions per minute or more, and the read/write heads typically operate only tens of nanometers over the magnetic surface of the disks. The platters are typically made of aluminum or of glass and ceramic, and a coating of magnetic material is deposited on the surface of each disk using a method designed to provide a thin, uniform layer of magnetic material, such as vacuum deposition processes. One such vacuum deposition process is known as magnetron sputtering, which is used in some examples to apply both magnetic and non-magnetic layers configured to control the grain size and orientation of the magnetic layers.

Magnetron sputtering in one example is performed by depositing a material such as CrOₓ on the disk surface by using a magnetron to create a strong electromagnetic field that confines charged plasma particles near the surface of the sputter source material (also called target material) in a high vacuum. The particles are ejected from a material source in one such a sputtering process by applying a voltage between the source material and the disk, which ionizes the argon atoms and creates a plasma of argon ions and electrons. The charged argon ions accelerate toward the source material due to the electromagnetic field, and ion collision ejects source material atoms which are deposited on the disk surface. Electrons released during argon ionization are accelerated toward the disk substrate as well, often colliding with other argon atoms and creating more argon ions and free electrons. A magnetron is used to form a strong magnetic field near the source material surface, causing free electrons and argon ions to congregate near the source material, thereby accelerating the collision process and increasing the rate of source material ejection, and reducing potential electron or argon damage to the disk surface.

Magnetic disk layers such as those formed by sputtering are often covered with a protective coating layer using a similar sputtering process, and a lubricant layer is often applied such as by dipping the disk in a solvent solution containing the lubricating polymer. The disks are then buffed and checked for surface defects, as even minor surface defects can result in corrupted data or damage to the head assembly that reads/writes the platter having the defect.

It is therefore desirable to manufacture hard disk platters in a way that ensures the disk surface is free of defects, and has even layers of applied materials.

### SUMMARY

One example embodiment comprises a method of operating a disk coating apparatus for magnetic data storage disks, including transporting a disk in a disk holding fixture from a first coating area to a second coating area via a plurality of roller wheels along a first path, and adjusting a disk transport wheel located along the first path between the first coating area and the second coating area within a sealed enclosure such that deflection of the disk holding fixture when traversing the disk transport wheel is reduced.

In a further example, adjusting the position of the disk transport wheel relative to the disk coating apparatus is performed by adjusting a leadscrew coupled to the disk holding fixture and a frame of the disk coating apparatus. In a further example, the leadscrew is adjusted via a rotary vacuum feedthrough configured to preserve vacuum in a coating area of the disk coating apparatus.

In another example, position of the disk transport wheel being adjusted is different under vacuum than under atmospheric pressure.

In a further example, adjustment of the disk transport wheel is verified by processing a test disk or a test disk holding fixture and measuring at least one of position over time or forces applied to the test disk or test disk holding fixture during transport through the disk coating apparatus

The details of one or more examples of the disclosure are set forth in the accompanying drawings and the description below. Other features and advantages will be apparent from the description and drawings, and from the claims.

### BRIEF DESCRIPTION OF THE FIGURES

FIG. 1 shows a block diagram of a disk coating apparatus, consistent with an example embodiment.

FIG. 2 is an isometric view of a compartment of a disk coating apparatus, consistent with an example embodiment.

FIG. 3 is a side view of a disk coating apparatus having multiple compartments, consistent with an example embodiment.

FIG. 4 shows an opposite side view of a disk coating apparatus having multiple compartments, consistent with an example embodiment.

FIG. 5 shows an adjustable idler wheel assembly, consistent with an example embodiment.

FIG. 6 is an isometric view of an adjustable idler wheel assembly, consistent with an example embodiment.

FIG. 7 is an isometric view of a disk coating apparatus having multiple compartments and having an externally adjustable idler wheel, consistent with an example embodiment.

FIG. 8 is a flowchart of a method of adjusting an externally adjustable idler wheel of a disk coating apparatus, consistent with an example embodiment.

FIG. 9 is a computerized disk coating apparatus control system, consistent with an example embodiment.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to define these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Magnetic disks in disk drives typically include a variety of materials, such as a substrate layer, a magnetic layer, and a protective layer deposited on an aluminum or glass/ceramic disk, using methods such as sputtering to provide a thin, uniform layer of magnetic material. Deposition of these various materials is performed in some examples by carrying a disk in a disk holding fixture that travels through various application stages, such as a base layer configured to control the grain size and orientation of a magnetic layer, a magnetic layer, and a protective layer such as a protective coating or lubricating coating applied to the magnetic layer. Materials deposited in these various stages are often applied via a vapor deposition process such as sputtering, in which applied material can accumulate on the disk holding fixtures as well as on the disks.

This accumulated material can be jarred loose from the disk holding fixture if the disk holding fixture is jarred during operation, resulting in potential movement of accumulated material from the disk holding fixture to the surface of the disk being processed. If such material adheres to the surface of the disk, it can result in surface asperities or flaws that can result in loss of data or can interfere with flight of a read/write head over the disk. Similarly, jarring the disk holding fixture can result in movement of the disk in the fixture, resulting in scratches on the disk surface that can similarly result in loss of data. Such disks are often therefore rejected in quality control screening if flaws such as these are found, resulting in lost time, materials, and efficiency.

As disk manufacturers work to improve efficiency of disk manufacturing processes, the speed at which disk coating and transport mechanisms operate becomes increasingly faster. This not only results in processing a greater number of disks per hour, but can also increase any jarring effect felt by the disk or disk holding fixture as a result of misalignment in the transport mechanism. This increase in jarring can result in an increase in coating material dislodged from a disk holding fixture or other part of the disk processing apparatus, resulting in flawed disks.

Some embodiments therefore seek to reduce the possibility of material being jarred loose from a disk holding fixture when moving between stages within a disk coating apparatus, such as by providing adjustable idler or drive wheels to guide the disk holding fixture when the disk holding fixture is moving, such as between coating stages in the disk coating apparatus. The position of the wheel or wheels can be adjusted to minimize jarring the disk holding fixture as the fixture comes into contact with the wheel and leaves contact with the wheel, providing smooth transport for the fixture and disk through the disk coating apparatus.

In one such example, the adjustable wheel comprises an externally adjustable wheel that can be adjusted while the interior of the disk coating apparatus is under vacuum, including the wheel or wheels being adjusted. Because the position of some parts of the apparatus may move or shift slightly when the disk coating apparatus is brought under vacuum, this can help ensure that the wheel is adjusted appropriately for vacuum conditions rather than simply being adjusted under atmospheric pressure and being potentially misaligned when brought under vacuum.

Proper adjustment of the wheel alignment is verified in some examples such as by optically or mechanically aligning the wheel being adjusted with other wheels, while in other examples a test disk, test disk holding fixture, or other apparatus having position or acceleration sensing capability is employed to characterize the smoothness of travel through the disk coating apparatus. If acceleration or change of position perpendicular to the direction of transport of the disk is seen when the disk holding fixture contacts the wheel under adjustment, it can be determined that the wheel can be further adjusted to minimize the jarring effect of the wheel on the disk holding fixture and disk assembly. Adjusting the wheel to minimize or reduce jarring the disk holding fixture and disk during transport can therefore improve disk reliability and reduce the number of defective disks produced by the disk coating apparatus, making the disk coating process more efficient and less expensive.

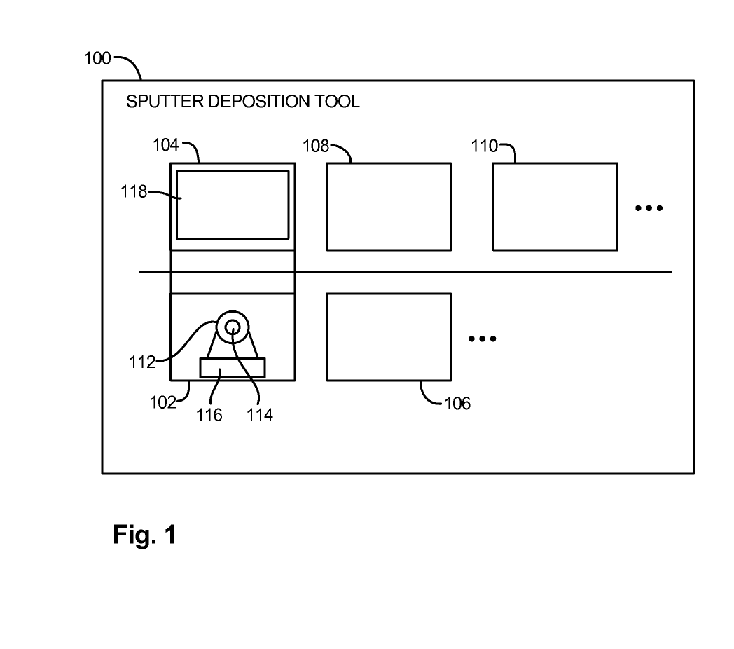

FIG. 1 shows a block diagram of a disk coating apparatus, consistent with an example embodiment. Here, the disk coating apparatus is a sputter deposition tool 100, which includes multiple compartments 102, 104, 106, 108, and 110 for coating a magnetic storage disk. Compartment 102 includes a disk holding fixture 112 for holding a disk 114 during coating or processing, such as for application of a nonmagnetic undercoat configured to orient the magnetic layer, application of a magnetic layer, application of a protective layer, and application of a lubricating layer. The disk holding fixture is operable to move between compartments of the disk coating apparatus, such as by moving a disk holding fixture support or drive unit 116 coupled to the disk holding apparatus. The disk is oriented vertically in some such examples, and both sides of the disk are coated at the same time in at least some of the compartments. In some examples, compartments are configured both at different horizontal and vertical levels, as shown at 102, 104, 106, 108, and 110. In some examples, the dis coating apparatus further includes one or more stages that do not coat the disk, such as compartment 104 comprising etching source 118 which is operable to bombard surfaces of components of the disk coating apparatus such as disk holding fixture 112 with suitable particles, such as plasma particles, to clean contaminants from the surface of the components.

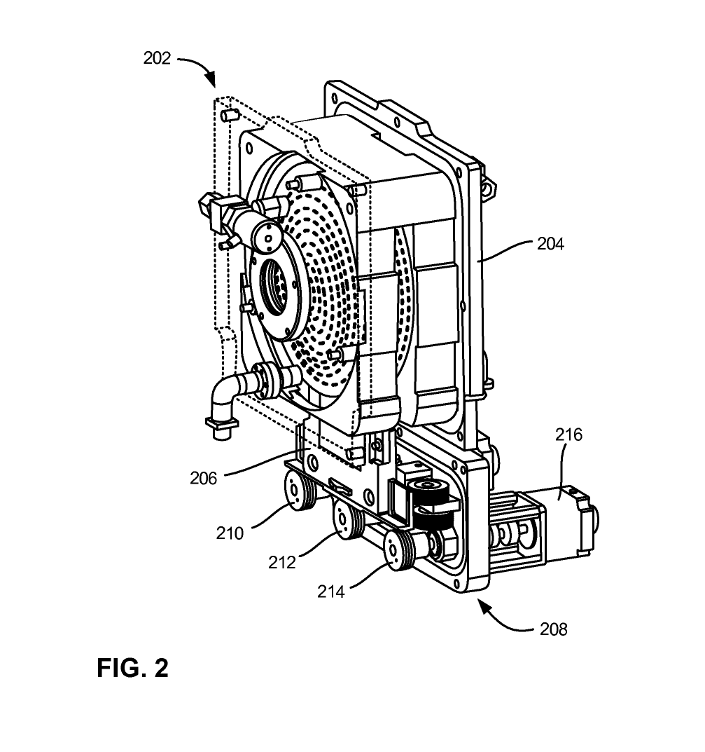

FIG. 2 is an isometric view of a compartment of a disk coating apparatus, consistent with an example embodiment. Here, a compartment 202 includes support plates and other members forming a frame 204, enclosing a disk that is being processed. The disk is supported by disk holding fixture 206, which is moved between compartments of the disk coating apparatus via a conveyor assembly 208, which includes wheels 210, 212, and 214. Some wheels in the conveyor assembly are motorized drive wheels, as shown by drive motor 216, while other wheels are idler wheels that serve to support and guide the disk holding fixture.

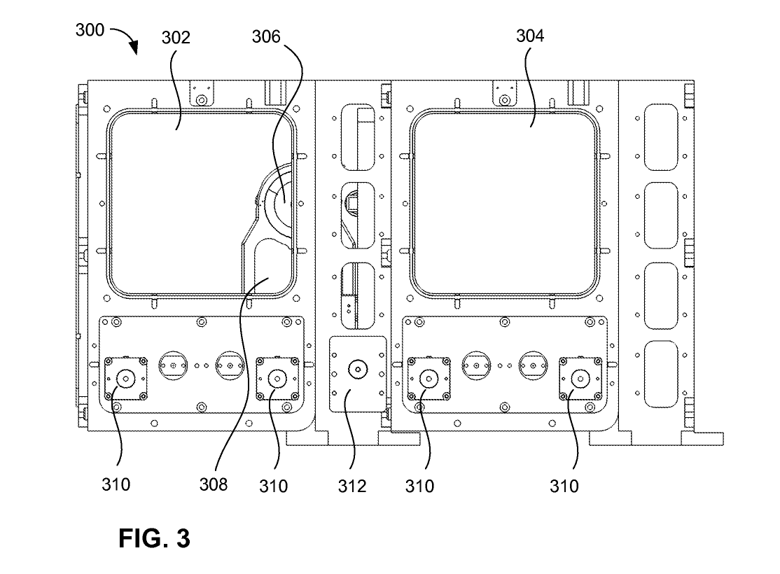

FIG. 3 is a side view of a disk coating apparatus having multiple compartments, consistent with an example embodiment. Here, a disk coating apparatus 300 has a first compartment 302 and a second compartment 304, operable to coat a magnetic recording disk 306 with different materials or to perform different process steps in manufacturing the magnetic recording disk. The disk 306 is supported by a disk holding fixture 308, which is transported from compartment to compartment by a conveyor assembly including various drive wheel assemblies 310 and an idler wheel assembly 312.

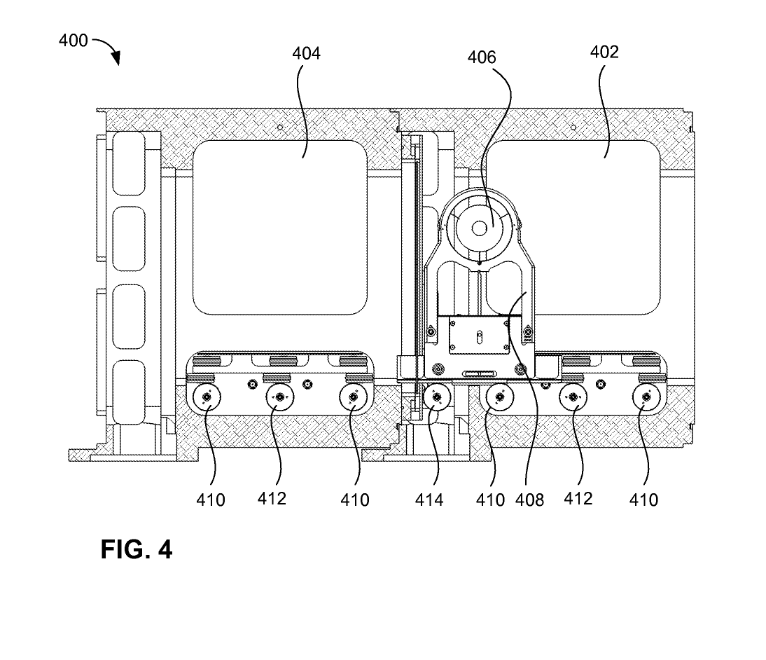

FIG. 4 shows an opposite side view of a disk coating apparatus having multiple compartments, consistent with an example embodiment. Here, the disk coating apparatus 400 has a first compartment 402 and a second compartment 404, each operable to perform a process step such as coating magnetic recording disk 406. Disk holding fixture 408 includes a base portion that is transported along a conveyor assembly that comprises drive wheels 410 and idler wheels 412 in each compartment, and an idler wheel 414 between the two compartments.

The idler wheels and drive wheels in some embodiments include fixed wheels, such as wheels that are not adjustable when the disk coating apparatus is operational or when the compartments are under vacuum. In the example presented here, at least one of the drive wheels 410 or idler wheels 412 and 414 is adjustable under vacuum, such as by use of a lead screw assembly that can be operated while the disk coating apparatus is operational or is under vacuum to provide for smooth transport of disk holding fixture 408.

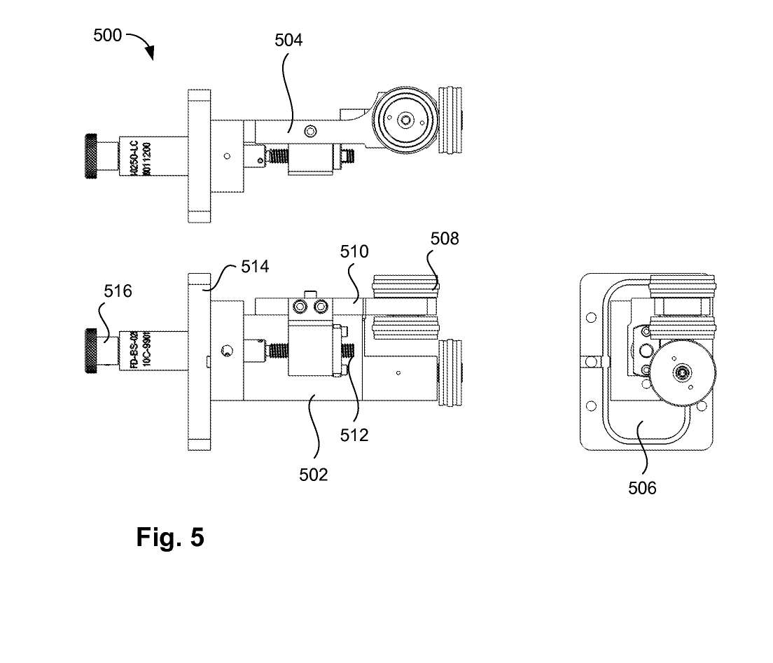

FIG. 5 shows an adjustable idler wheel assembly, consistent with an example embodiment. Here, three orthogonal views of the idler wheel assembly are illustrated, including a top view 502, a side view 504, and an end view 506. The idler wheel assembly in this example includes idler wheels 508 mounted to an idler wheel support 510 that is coupled to leadscrew 512. The leadscrew 512 is also coupled to a flange 514 that is mounted to the frame or outer wall of the disk coating apparatus, thereby sealing the disk coating apparatus and allowing for external adjustment of the position of wheels 508 relative to the flange 514 and frame of the disk coating apparatus by turning knob 516, which in turn rotates leadscrew 512.

These views show an example of an idler wheel assembly that is adjustable under vacuum, or while a disk coating apparatus is sealed. Because the position of the wheels may shift relative to their positon under atmospheric pressure when brought under vacuum, providing for adjustment of idler wheels 508 while the disk coating apparatus is under vacuum enables more accurate adjustment of the wheels to minimize jarring while a disk holding fixture is transported or conveyed across the wheels during disk processing.

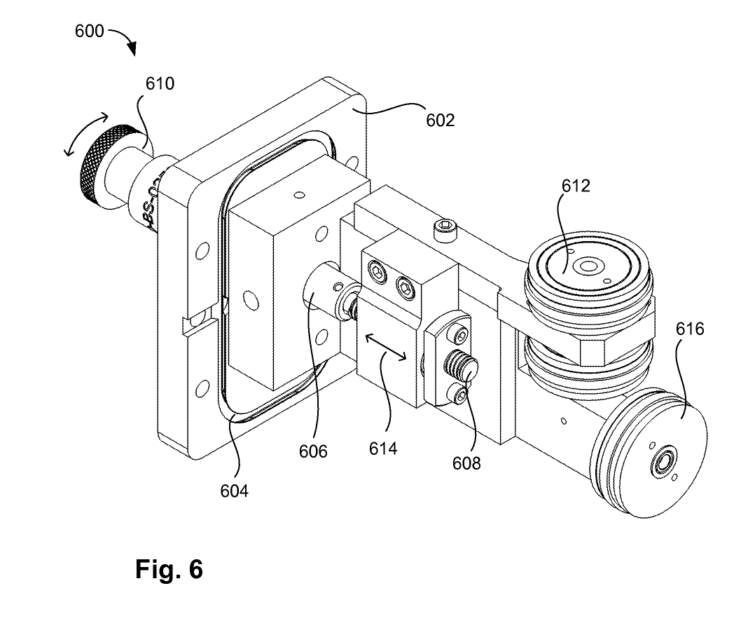

FIG. 6 is an isometric view of an adjustable idler wheel assembly, consistent with an example embodiment. Here, an idler wheel assembly 600 includes a flange portion 602 that supports a seal 604 operable to seal the idler wheel assembly to a frame or wall of a disk coating apparatus, thereby allowing the disk coating apparatus to maintain a vacuum under operation. A rotary vacuum feedthrough 606 facilitates adjustment of leadscrew 608 by turning adjustment knob 610, thereby moving the position of idler wheels 612 relative to the disk coating apparatus frame and flange 602. In other examples, other mechanisms are employed to alter the position of idler wheels 612 relative to the disk coating apparatus frame and flange 602, such as a linear actuator, gear drive, or other mechanism.

Although FIG. 6 shows an adjustable idler wheel assembly where the position of wheels 612 is adjustable in one direction as indicated by arrows 614, other examples include adjustability in another dimension, such as parallel to the surface of flange 602, or adjustability of other wheels such as wheel 616 in one or more dimensions. In the example shown in FIG. 6, turning the knob 610 results in rotation of rotary vacuum feedthrough 606, which is not threaded, but which is coupled to rotary screw 608. Rotary screw 608 engages a threaded portion of a wheel mount assembly as shown at 614, allowing the threaded portion of the wheel mount assembly 614 to move relative to other parts of the wheel mount assembly and the flange 602 in response to turning the screw.

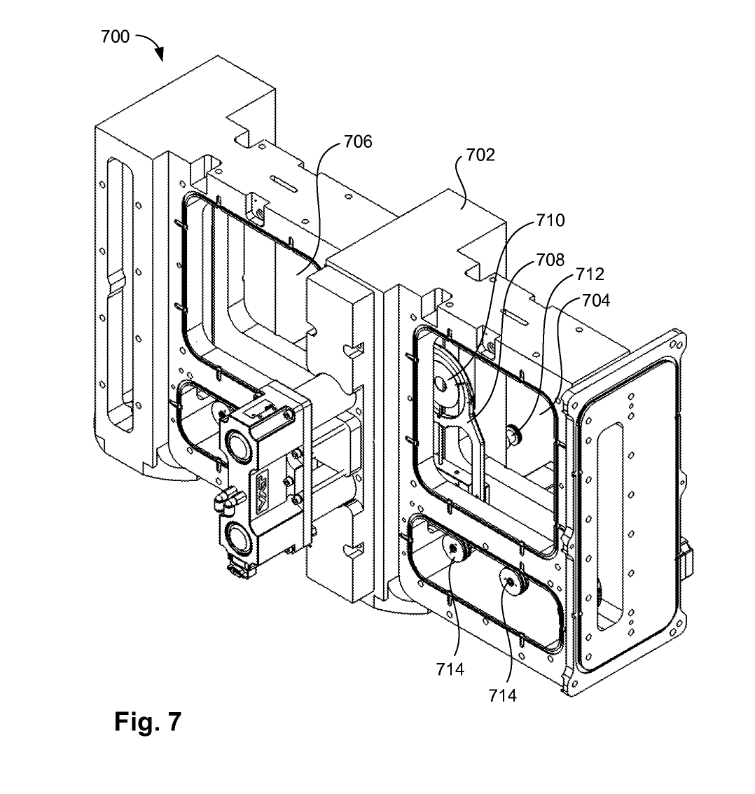

FIG. 7 is an isometric view of a disk coating apparatus having multiple compartments and having an externally adjustable idler wheel, consistent with an example embodiment. Here, a disk coating apparatus comprises a frame 702, defining a first compartment 704 and a second compartment 706. A disk holding fixture 708 supports a magnetic recording disk 710 during manufacture, such as to have different coatings applied in compartments 704 and 706.

The disk holding fixture 708 and disk 710 are transported between compartments by a conveyor assembly, including a series of drive wheels and idler wheels. The compartments in the example shown are configurable such that multiple compartments can be attached to one another by attaching a series of frames 702 to one another, such as is shown generally at 700. Because the frames of the various compartments making up the stages of a disk coating apparatus may not align with one another perfectly, some adjustment of the wheels of the conveyor assembly may be required to minimize or reduce jarring the disk holding fixture as it moves from wheel to wheel and from compartment to compartment of the disk coating apparatus.

The disk coating apparatus shown at 700 therefore includes an idler wheel assembly 712 (such as is pictured in FIGS. 5 and 6; the adjustment knob is visible at 712) that is adjustable external to the disk coating apparatus while the disk coating apparatus is under vacuum, thereby providing for improved alignment between wheels of the different compartments of the disk coating apparatus. In other embodiments, other wheel assemblies such as drive wheels 714, other idler wheels, or other such guides will be similarly adjustable to ensure smooth transport of the disk holding fixture under vacuum.

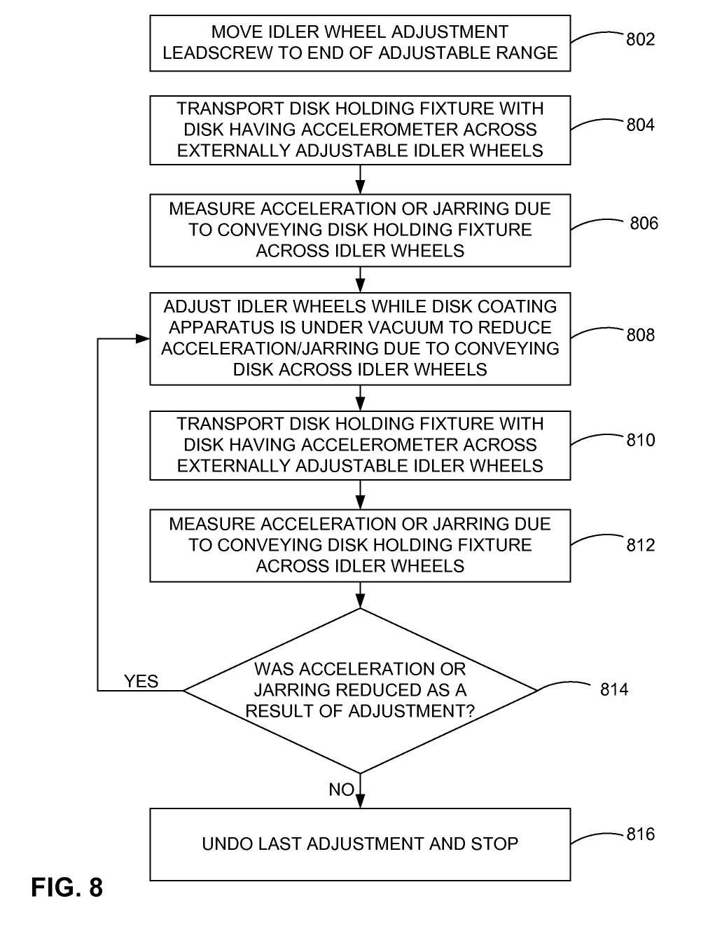

FIG. 8 is a flowchart of a method of adjusting an externally adjustable idler wheel of a disk coating apparatus, consistent with an example embodiment. At 802, the leadscrew attached to the disk coating apparatus frame via an idler wheel assembly flange and a rotary vacuum feedthrough is adjusted to one end of its adjustable range. The disk coating apparatus is brought under vacuum to simulate a normal operating environment, and a disk holding fixture with a disk having an accelerometer attached thereto is transported across the externally adjustable idler wheels at 804. The accelerometer enables measurement and characterization of the jarring or acceleration that the disk experiences as a result of the disk holding fixture traversing the externally adjustable idler wheel at 806, and the idler wheel is adjusted incrementally at 808 to reduce the acceleration/jarring experienced by the disk coating apparatus and disk.

After the idler wheels are adjusted at 808, the disk holding fixture and the disk having an accelerometer attached thereto are again transported across the externally adjustable idler wheels at 810. The acceleration or jarring experienced due to the disk holding fixture traversing the externally adjustable idler wheel is again measured at 812, and is compared to the jarring or acceleration previously measured at 814. If the acceleration or jarring due to the adjustment made at 808 was reduced relative to the acceleration or jarring measured at 806, the idler wheels are further incrementally adjusted at 808 and the process repeats. If the acceleration or jarring due to the adjustment made at 808 was not reduced relative to the acceleration or jarring measured at 806, the idler screw has been adjusted past the adjustment point where minimal acceleration or jarring will be experienced, and the last adjustment is undone at 816 and the process is stopped.

FIG. 8 illustrates a method of adjusting the idler wheels that can be automated, such as by a computer or other disk coating apparatus control system configured to adjust and operate the disk coating apparatus. In other examples, various other methods are employed such as to improve speed or accuracy of adjustment, such as using Newton's method or other methods of estimation and zeroing in on an adjustment setting resulting in minimal jarring or acceleration more quickly. In one such example, a coarse estimate is determined, such as which of ten segments of the leadscrew operating area results in the least acceleration or jarring, and a fine setting is subsequently determined, such as which of ten positions within the selected coarse segment results in the least acceleration or jarring. This allows determination of a wheel position from among 100 possibilities with 20 or fewer trials, demonstrating efficiency relative to simply trying each of the 100 positions sequentially.

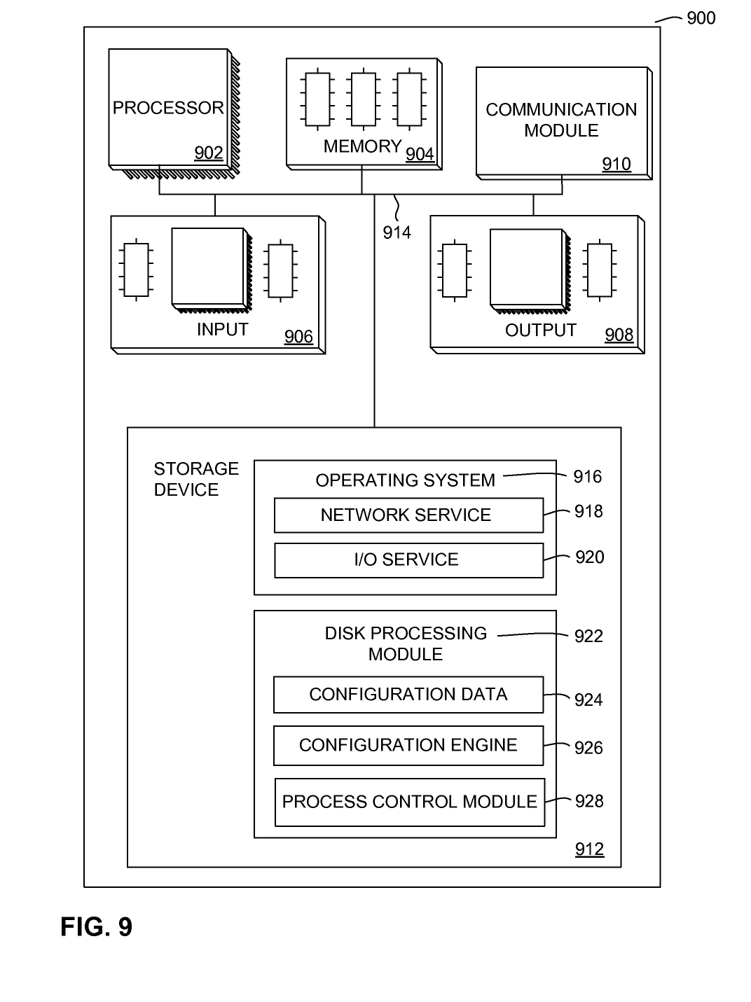

FIG. 9 is a computerized disk coating apparatus control system, consistent with an example embodiment. FIG. 9 illustrates only one particular example of computing device 900, and other computing devices 900 may be used in other embodiments. Although computing device 900 is shown as a standalone computing device, computing device 900 may be any component or system that includes one or more processors or another suitable computing environment for executing software instructions in other examples, and need not include all of the elements shown here.

As shown in the specific example of FIG. 9, computing device 900 includes one or more processors 902, memory 904, one or more input devices 906, one or more output devices 908, one or more communication modules 910, and one or more storage devices 912. Computing device 900, in one example, further includes an operating system 916 executable by computing device 900. The operating system includes in various examples services such as a network service 918 and An I/O service 920 such as an interface to a physical disk coating apparatus. One or more applications, such as disk processing module 922 are also stored on storage device 912, and are executable by computing device 900.

Each of components 902, 904, 906, 908, 910, and 912 may be interconnected (physically, communicatively, and/or operatively) for inter-component communications, such as via one or more communications channels 914. In some examples, communication channels 914 include a system bus, network connection, inter-processor communication network, or any other channel for communicating data. Applications such as disk processing module 922 and operating system 916 may also communicate information with one another as well as with other components in computing device 900.

Processors 902, in one example, are configured to implement functionality and/or process instructions for execution within computing device 900. For example, processors 902 may be capable of processing instructions stored in storage device 912 or memory 904. Examples of processors 902 include any one or more of a microprocessor, a controller, a digital signal processor (DSP), an application specific integrated circuit (ASIC), a field-programmable gate array (FPGA), or similar discrete or integrated logic circuitry.

One or more storage devices 912 may be configured to store information within computing device 900 during operation. Storage device 912, in some examples, is known as a computer-readable storage medium. In some examples, storage device 912 comprises temporary memory, meaning that a primary purpose of storage device 912 is not long-term storage. Storage device 912 in some examples is a volatile memory, meaning that storage device 912 does not maintain stored contents when computing device 900 is turned off. In other examples, data is loaded from storage device 912 into memory 904 during operation. Examples of volatile memories include random access memories (RAM), dynamic random access memories (DRAM), static random access memories (SRAM), and other forms of volatile memories known in the art. In some examples, storage device 912 is used to store program instructions for execution by processors 902. Storage device 912 and memory 904, in various examples, are used by software or applications running on computing device 900 such as disk processing module 922 to temporarily store information during program execution.

Storage device 912, in some examples, includes one or more computer-readable storage media that may be configured to store larger amounts of information than volatile memory. Storage device 912 may further be configured for long-term storage of information. In some examples, storage devices 912 include non-volatile storage elements, such as magnetic hard discs, optical discs, floppy discs, flash memories, or forms of electrically programmable memories (EPROM) or electrically erasable and programmable (EEPROM) memories.

Computing device 900, in some examples, also includes one or more communication modules 910. Computing device 900 in one example uses communication module 910 to communicate with external devices via one or more networks, such as one or more wireless networks. Communication module 910 may be a network interface card, such as an Ethernet card, an optical transceiver, a radio frequency transceiver, or any other type of device that can send and/or receive information. Other examples of such network interfaces include Bluetooth, 3G or 4G, WiFi radios, and Near-Field Communications (NFC), and Universal Serial Bus (USB). In some examples, computing device 900 uses communication module 910 to communicate with an external device, such as a disk coating apparatus.

Computing device 900 also includes in one example one or more input devices 906. Input device 906, in some examples, is configured to receive input from a user through tactile, audio, or video input. Examples of input device 906 include a touchscreen display, a mouse, a keyboard, a voice responsive system, video camera, microphone or any other type of device for detecting input from a user.

One or more output devices 908 may also be included in computing device 900. Output device 908, in some examples, is configured to provide output to a user using tactile, audio, or video stimuli. Output device 908, in one example, includes a display, a sound card, a video graphics adapter card, or any other type of device for converting a signal into an appropriate form understandable to humans or machines. Additional examples of output device 908 include a speaker, a light-emitting diode (LED) display, a liquid crystal display (LCD), or any other type of device that can generate output to a user.

Computing device 900 may include operating system 916. Operating system 916, in some examples, controls the operation of components of computing device 900, and provides an interface from various applications such as disk processing module 922 to components of computing device 900. For example, operating system 916, in one example, facilitates the communication of various applications such as recommendation module 922 with processors 902, communication unit 910, storage device 912, input device 906, and output device 908. Applications such as disk processing module 922 may include program instructions and/or data that are executable by computing device 900. As one example, recommendation module 922 and its configuration database 924, configuration engine 926, and process control module 928 may include instructions that cause computing device 900 to perform one or more of the operations and actions described in the examples presented herein.

In one such example, disk processing module 922 controls a magnetic disk coating or processing apparatus via inputs 906 and outputs 908, using I/O services 920 provided by operating system 916. The disk processing module loads configuration data regarding processing steps and parameters from configuration data 924, and performs various configuration or startup processes such as adjusting a wheel of a transport assembly to minimize jarring of a disk holding fixture using configuration engine 926, such as by performing the method of FIG. 8. Disk processing is then performed via process control module 928, which controls normal operation of the disk coating apparatus.

Although specific embodiments have been illustrated and described herein, any arrangement that achieve the same purpose, structure, or function may be substituted for the specific embodiments shown. This application is intended to cover any adaptations or variations of the example embodiments described herein. These and other embodiments are within the scope of the following claims and their equivalents.

1. A method of operating a disk coating apparatus for magnetic data storage disks, comprising:
transporting a disk in a disk holding fixture from a first coating area to a second coating area via a plurality of roller wheels along a first path; and
adjusting a disk transport wheel located along the first path between the first coating area and the second coating area within a sealed enclosure.

2. The method of operating a disk coating apparatus for magnetic data storage disks of claim 1, wherein adjusting a disk transport wheel comprises adjusting the disk transport wheel such that deflection of the disk holding fixture when traversing the disk transport wheel is reduced relative to an unadjusted position.

3. The method of operating a disk coating apparatus for magnetic data storage disks of claim 1, wherein the disk transport wheel comprises a disk transport drive wheel or a disk transport idler wheel.

4. The method of operating a disk coating apparatus for magnetic data storage disks of claim 1, wherein adjusting a disk transport wheel comprises adjusting a position of the disk transport wheel relative to the disk coating apparatus by adjusting a leadscrew or other mechanism coupled to the disk holding fixture and a frame of the disk coating apparatus.

5. The method of operating a disk coating apparatus for magnetic data storage disks of claim 4, wherein the leadscrew is adjusted via a rotary vacuum feedthrough configured to preserve vacuum in a coating area of the disk coating apparatus.

6. The method of operating a disk coating apparatus for magnetic data storage disks of claim 1, wherein adjusting a disk transport wheel is performed when the disk transport wheel and disk coating apparatus are under vacuum.

7. The method of operating a disk coating apparatus for magnetic data storage disks of claim 1, further comprising verifying adjustment of the disk transport wheel by processing a test disk or a test disk holding fixture and measuring at least one of position over time or forces applied to the test disk or test disk holding fixture during transport through the disk coating apparatus.

8. The method of operating a disk coating apparatus for magnetic data storage disks of claim 1, wherein adjusting a disk transport wheel comprises adjusting the disk transport wheel in at least a coarse adjustment stage and a fine adjustment stage.

9. The method of operating a disk coating apparatus for magnetic storage disks of claim 1, wherein the first area and second area comprise one or more of a base layer application area, a magnetic coating application area, a protective layer application area, and a lubrication layer application area.

10. A disk coating apparatus for magnetic data storage disks, comprising:
a frame assembly;
a first coating area for coating a magnetic storage disk;
a second coating area for coating the magnetic storage disk;
a disk holding fixture operable to hold the magnetic storage disk and to transport the disk from the first coating area to the second coating area along a first path; and
an adjustable disk transport wheel operable to guide the disk holding fixture along the first path between the first coating area and the second coating area within a sealed enclosure, the disk transport wheel adjustable such that deflection of the disk holding fixture when traversing the disk transport wheel is reduced relative to an unadjusted position.

11. The disk coating apparatus for magnetic data storage disks of claim 10, wherein the disk transport wheel comprises a disk transport idler wheel or a disk transport drive wheel.

12. The disk coating apparatus for magnetic data storage disks of claim 10, further comprising a leadscrew or other mechanism coupled the disk transport wheel and the frame of the disk coating apparatus, such that adjusting the disk transport wheel comprises adjusting a position of the disk transport wheel relative to the disk coating apparatus by adjusting the leadscrew or other mechanism.

13. The disk coating apparatus for magnetic data storage disks of claim 12, further comprising rotary vacuum feedthrough providing for adjustment of the leadscrew, the rotary vacuum feedthrough configured to preserve vacuum in a coating area of the disk coating apparatus.

14. The disk coating apparatus for magnetic data storage disks of claim 10, further comprising a vacuum pump operable to bring the disk coating apparatus under vacuum, and wherein the disk transport wheel is adjustable when the disk transport wheel and disk coating apparatus are under vacuum.

15. The disk coating apparatus for magnetic data storage disks of claim 14, wherein position of the disk transport wheel being adjusted is different under vacuum than under atmospheric pressure.

16. The disk coating apparatus for magnetic data storage disks of claim 10, further comprising verifying adjustment of the disk transport wheel by processing a test disk or a test disk holding fixture and measuring at least one of position over time or forces applied to the test disk or test disk holding fixture during transport through the disk coating apparatus.

17. A wheel assembly for use in a magnetic storage disk coating apparatus, comprising:
at least one wheel configured to transport a disk in a disk holding fixture from a first coating area of the disk coating apparatus to a second coating area along a first path; and
a wheel mount supporting the at least one wheel and adjustably configurable to move the position of the wheel within a sealed enclosure such that such that deflection of the disk holding fixture when traversing the disk transport wheel is reduced.

18. The wheel assembly of claim 17, further comprising a leadscrew or other mechanism coupled to the wheel mount and to a frame of the magnetic storage disk coating apparatus, such that turning the leadscrew or adjusting the other mechanism adjusts the position of the wheel mount and wheel relative to the frame.

19. The wheel assembly of claim 17, further comprising a rotary vacuum feedthrough configured to provide for adjustment of the leadscrew from outside the magnetic storage disk coating apparatus while preserving a vacuum in a coating area of the magnetic storage disk coating apparatus.

20. A machine-readable medium with instructions stored thereon, the instructions when executed operable to cause a computerized system to:
transport a disk in a disk holding fixture from a first coating area of a disk coating apparatus for magnetic storage disks to a second coating area via a plurality of roller wheels along a first path; and
adjust a disk transport wheel located along the first path between the first coating area and the second coating area within a sealed enclosure such that deflection of the disk holding fixture when traversing the disk transport wheel is reduced.
